(19) United States
(12) Patent Application Publication
(10) Pub. No.: US 2007/0029192 A1
(43) Pub. Date: Feb. 8, 2007

(54) Tube cathode for use in sputter processes

(76) Inventors: Manfred Schuhmacher, Alzenau (DE); Gerhard Joos, Obernburg (DE)

Correspondence Address: FULBRIGHT & JAWORSKI, LLP, 666 FIFTH AVE, NEW YORK, NY, 10103-3198, US

(21) Appl. No.: 11/441,271

(22) Filed: May 25, 2006

(30) Foreign Application Priority Data
Aug. 2, 2005 (EP) 050 16 738

(51) Int. Cl. C23C 14/00

(52) U.S. Cl. 204/298.01

(57) ABSTRACT

The invention relates to a tube cathode with a target carrier and a target. The target can herein be a single- or a multi-part target. Between target carrier and target are placed several annular elements of a thermally conductive material along the longitudinal axis of the target carrier. The annular elements are separated from one another by narrow rings. The target has on at least one end face a chamfer, which permits sliding the target readily over the discrete annular elements.

### BACKGROUND AND SUMMARY OF THE INVENTION

This application claims priority from European Patent Application No. 05 016 738 filed Aug. 2, 2005, incorporated herein by reference in its entirety.

The invention relates to a tube cathode for use, e.g., in sputter processes.

Apart from the so-called planar cathodes, tube cathodes are used increasingly more frequently since these have very high efficiency when coating substrates. Such tube cathodes comprise a target carrier, a target and a magnet system, which is stationary in the target carrier.

When the target is consumed by the sputter process, the target is disposed of together with the target carrier and a new target with new target carrier is installed in a corresponding sputter unit.

A method for the production of cylindrical sputter targets is already known, in which a cooling tube is formed comprising passages through which a cooling means flows (US 2001/0047936 A1). In addition, several rings are produced comprised of a material to be sputtered. The produced rings are subsequently put over the cooling tube such that the protruding parts of these rings form a layer on a substrate when they are sputtered.

A sputter target is furthermore known comprising a tube as well as a sleeve, which is comprised of sputter material, wherein the inner diameter of the sleeve is greater than the outer diameter of the tube, such that an annular space is formed between tube and sleeve (U.S. Pat. No. 6 409 897 B1). The annular space is at least partially occupied by a thermally conducting material, this thermally conducting material including a material comprised of individual particles, which material flows at ambient temperature.

A cylindrical target is furthermore known comprising cylindrical target material located on a carrier (US 2003/0136662 A1). Between the target material and the carrier is a buffer element. This buffer element may be a carbon felt.

Similarly, between a target carrier and a target an electrically conducting matt is inserted (U.S. Pat. No. 6 787 011 B2).

Furthermore, a target arrangement is known with a cylindrical carrier element and at least one hollow cylindrical target comprising a target material, which target encompasses the carrier element at least in sections. (DE 10 2004 031 161 A1). Between the carrier element and the target a clamping ring or one or several clamping wedges are provided.

Lastly, yet another target carrier arrangement is known, which comprises a carrier, on which a target shell is disposed (DE 102 31 203 A1). The target shell herein is formed by a target sleeve, which is slid onto the carrier. Between the carrier and the target sleeve at least one clamping element is operatively disposed.

The invention addresses the problem of facilitating the sliding of a single- or multi-part target tube onto a carrier tube.

The problem is resolved according to the present invention.

The invention consequently relates to a tube cathode with a target carrier and a target. The target may herein be comprised of a single or of multiple parts. Between the target carrier and target several annular elements of a thermally conductive material are placed along the longitudinal axis of the target carrier. Narrow rings separate the annular elements from one another. The target has on at least one end face a chamfer which makes it possible to slide the target easily over the discrete annular elements.

The advantage attained with the invention lies in particular therein that even targets which are difficult to manage, for example targets of molybdenum or ITO with a low thermal coefficient of expansion, can be applied more readily than was previously the case, since bonding is omitted. In addition, the target pieces sputtered off can be utilized again, since they are not contaminated by bonding agents. When using multi-part targets, the material stresses, which occur due to the heating of the target material through the sputter process, can be compensated thereby that between adjacent target rings a minimal expansion gap is provided.

Embodiment examples of the invention are depicted in the drawing and will be described in further detail below.

### BRIEF DESCRIPTION OF THE FIGURES

FIG. 1 is a tube cathode with a single-part target,

FIG. 2 is a tube cathode with a multi-part target,

FIG. 3 is a carrier tube with a target part,

FIG. 4 is a carrier tube with two target parts,

FIG. 5 is a carrier tube with two ring targets slid onto it.

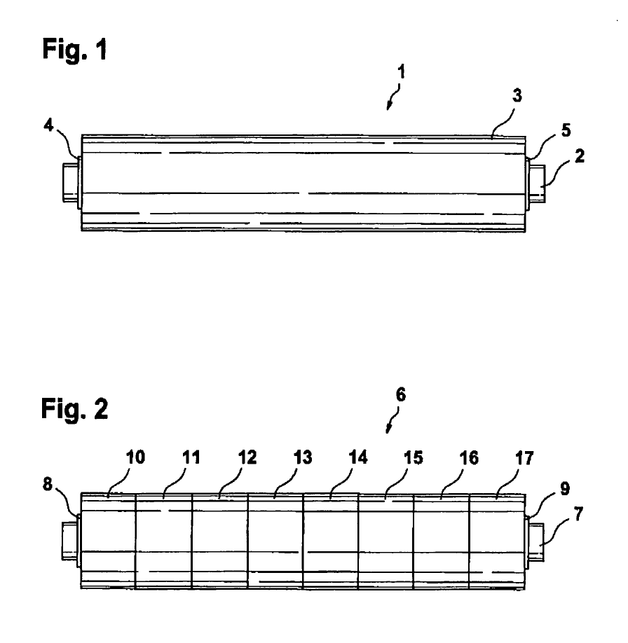

FIG. 1 depicts a tube cathode 1 in side view. A carrier tube 2 is shown and a single-part target 3 as well as two securement rings 4, 5.

### DETAILED DESCRIPTION

Another tube cathode 6 is shown in FIG. 2. Again, a carrier tube 7 is shown as well as two securement rings 8, 9. However, the target in this case is composed of several ring targets 10 to 17.

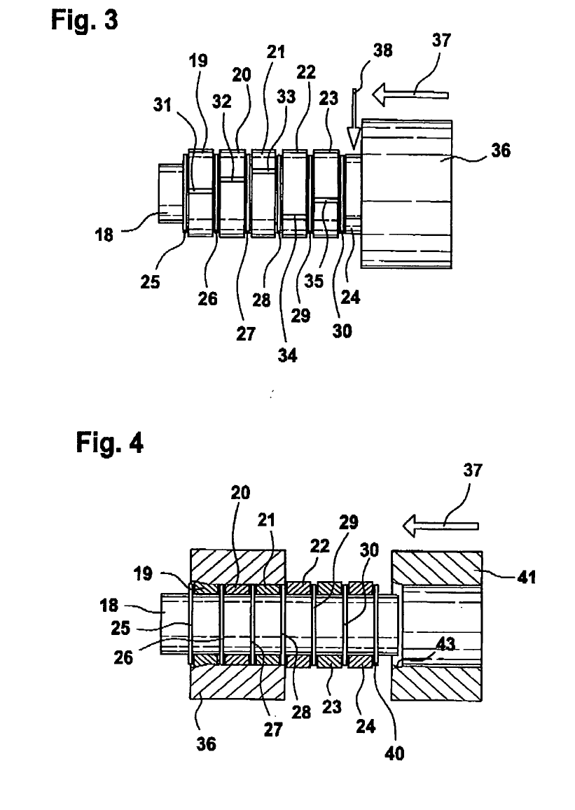

In FIG. 3 all except one of the ring targets are removed, such that the surface of a carrier tube 18 is visible. This carrier tube 18 has several segments, in each of which is disposed a graphite foil band 19 to 24. This graphite foil band is comprised of natural graphite, which has been converted into a graphite intercalation compound. Corresponding foils are for example distributed under the designation SIGRAFLEX by SGL Technik GmbH, D-86405 Meitingen.

The segments of the carrier tube 18 are formed by rings 25 to 30 extending equidistantly about the cylindrical circumference of the carrier tube 18, and between adjacent rings extend the graphite foil bands 19 to 24. Within a graphite foil band 19 to 24 joint lines 31 to 35 are provided in the direction of the circumference of the carrier tube 18 offset relative to one another such that a linear disposition of several joint lines is excluded.

A ring target 36 is slid onto the graphite foil band 24 in the direction of arrow 37. Hereby pressure is exerted in the direction of an arrow 38, such that the elastic graphite foil band 24 is compressed Its outer diameter is therefore less than the outer diameters of the other graphite foil bands 19 to 23, which are not yet compressed. In addition, its joint line has disappeared. When sliding the ring target 36 further, the graphite foil bands 19 to 23 are also compressed.

It is not necessary to equip the carrier tube 18 completely with graphite foil bands 19 to 24 and subsequently slide ring targets over the entire target length, which remains free. Rather, it is even conserving of material to insert only enough graphite foil bands 19 to 24 into the segments such that the ring target currently to be slid on is completely underlined with the foil. Only before sliding on the next target ring are the necessary further segments layed out with graphite foil bands. The target rings are consequently only slid over the particular graphite foil bands required in each instance. Only if a target tube is involved must it be slid completely over all segments layed out with graphite foil.

FIG. 4 depicts once again the configuration of FIG. 3, however with two sectioned ring targets 36, 41 and with sectioned graphite foil bands 19 to 24. The joint lines 31 to 35 are herein not visible. In addition to the ring target 36, which is shown after it has been slid on, a further ring target 41 is also evident, which is in the process of being slid on. Both ring targets 36, 41 have at their left end chamfers 42, 43 which facilitate the sliding-on onto the graphite foil bands 19 to 24. The outer diameter of the emplaced graphite foil bands 19 to 24 secured with a fast- setting adhesive is greater in the uncompressed state than the inner diameter of the ring target 41.

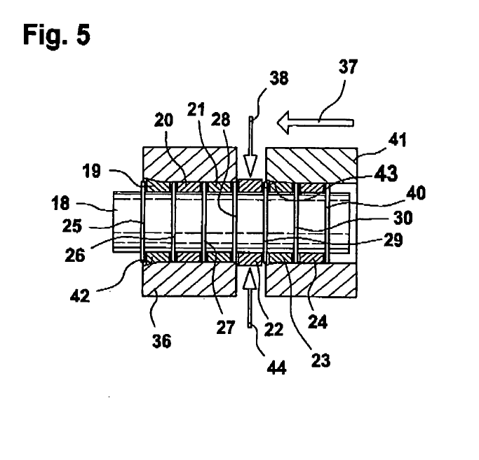

FIG. 5 shows once again the configuration according to FIG. 4, however with the ring target 41 having been shifted further to the left. It can be seen that through the chamfer 43 of the ring target 41, which is shifted to the left in the direction of arrow 37, the graphite foil band 22 is engaged at its upper edge. When sliding the ring target 41 further in the direction of arrow 37, forces are exerted in the direction of arrow 38, 44 onto the graphite foil band 22, such that it is compressed and lastly comes to lie with its upper edge at the same level as the upper edge of the rings 25 to 30, 40.

Prewarming the ring target 41 facilitates the sliding-on or pressing-on of the ring targets 41. The joint sites of the target rings 36, 41 are thus able to come to lie over the rings 25 to 30. In this way targets up to 4 m in length can be utilized without any problem.

By dividing the carrier tube 18 into segments by means of the rings 25 to 30 the frictional force acting onto the graphite foil bands 19 to 23 when sliding on the target tube is reduced, since the graphite foil bands 19 to 23 can stay themselves on the rings 25 to 30 and slipping of the graphite foil bands 19 to 23 is prevented. The graphite foil bands 19 to 23 can thereby be clamped under higher pressing between ring target 36 and carrier tube 18, which leads to better electric and thermal conductivity.

To prevent the graphite or the material of the rings 25 to 30 located in the expansion gaps of approximately 0.5 mm between adjacent ring targets 36, 41 from being eroded by the sputtering, which would lead to contamination of the layers to be deposited, the ring targets may be provided at the inner diameter with radial cut-ins or nose-pieces, which can mesh like tongue and groove. For example, the ring target 36 in FIG. 4 may have a recess above the foil band 21, while the ring target 41 could have a corresponding protrusion, which is introduced into the recess when the ring targets 36, 41 are slid together.

In this manner it is possible to prevent that the rings 25 to 30 and 40 are exposed to the bombardment of plasma particles, since these particles can only impinge on the ring targets.

The graphite foils utilized have a greater coefficient of thermal expansion perpendicularly to the layering than parallel thereto. Thermal expansion parallel to the layering is compensated by the joint lines 31 to 35. The greater thermal expansion perpendicularly to the layering causes that with suboptimal cooling the clamping of the foil between the ring target 36 and the carrier tube 18 is augmented, which, in turn, increases the heat transport such that the cooling increases.

1-13. (canceled)

14. A tube cathode for use in a sputter process with a target carrier and a target, wherein between target carrier and target a layer with good electric and thermal conductivity is located, wherein that the thermally well conducting layer is divided along the longitudinal axis of the target carrier into several discrete layers which are spaced apart from one another.

15. The tube cathode as claimed in claim 14, wherein said layer predominantly comprise of graphite.

16. The tube cathode as claimed in claim 14, wherein the target carrier and the target are tubular or cylindrical.

17. The tube cathode as claimed in claim 14, wherein several ring targets are disposed on one target carrier.

18. The tube cathode as claimed in claim 17, wherein a ring target has at least at one end a slip chamfer.

19. The tube cathode as claimed in claim 14, wherein each of the discrete layers is formed by a foil.

20. The tube cathode as claimed in claim 15, wherein each of the discrete layers is formed by a foil.

21. The tube cathode as claimed in claim 14, wherein the discrete layers are formed by graphite rings.

22. The tube cathode as claimed in claim 21, wherein each graphite ring is provided with a joint line extending transversely.

23. The tube cathode as claimed in claim 21, wherein the joint lines of the graphite rings are disposed on the circumference of the target carrier such that they are spatially offset with respect to one another.

24. The tube cathode as claimed in claim 22, wherein joint lines of the graphite rings are disposed on the circumference of the target carrier such that they are spatially offset with respect to one another.

25. The tube cathode as claimed in claim 14, wherein between the discrete layers are located rings which extend about the circumference of the target carrier.

26. The tube cathode as claimed in claim 17, wherein adjacent ring targets are formed such that they mesh at their end faces like tongue and groove.

27. The tube cathode as claimed in claim 14, wherein the target comprises molybdenum.

28. The tube cathode as claimed in claim 14, wherein the target comprises ITO.
